(19) United States
(12) Patent Application Publication
(10) Pub. No.: US 2025/0098234 A1
(43) Pub. Date: Mar. 20, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Shunsuke KAMIYA, Komatsu Ishikawa (JP)

(21) Appl. No.: 18/625,761

(22) Filed: Apr. 3, 2024

(30) Foreign Application Priority Data
Sep. 20, 2023 (JP) 2023-153941

(51) Int. Cl. H01L 29/06; H01L 21/02; H01L 21/265; H01L 29/66; H01L 29/78

(52) U.S. Cl. CPC H10D 62/109; H01L 21/02532; H01L 21/02579; H01L 21/26513; H10D 30/0297; H10D 30/668; H10D 62/127

(57) ABSTRACT

A semiconductor device according to an embodiment includes: first and second electrodes respectively provided on first and second main surfaces of a semiconductor layer; a first semiconductor region of a first conductivity type; a plurality of insulating regions formed to extend in a second direction orthogonal to a first direction from the second electrode toward the first electrode; a plurality of third electrodes provided in the plurality of insulating regions; a second semiconductor region of a second conductivity type sandwiched between the plurality of insulating regions, formed to extend in the second direction; a third semiconductor region of the first conductivity type located between the second semiconductor region and the first electrode; and a carrier conduction part formed to extend in the second direction in the second semiconductor region and electrically connected to the first electrode via a connection part not penetrating the third semiconductor region.

### CROSS-REFERENCE TO RELATED APPLICATIONS

This application is based upon and claims the benefit of priority from the prior Japanese Patent Application No. 2023-153941, filed on Sep. 20, 2023; the entire contents of which are incorporated herein by reference.

### FIELD

Embodiments described herein relate generally to a semiconductor device.

### BACKGROUND

A power metal oxide semiconductor field effect transistor (MOSFET) is used as an inverter for driving a motor or the like. In the power MOSFET, it is necessary to secure avalanche tolerance so that an element is not destroyed by counter electromotive force generated during switching operation.

As a method of improving avalanche tolerance, it is conceivable to prevent an operation of a parasitic bipolar transistor existing in the MOSFET. Since the parasitic bipolar transistor is easily operated by minority carriers accumulated in a base region, avalanche tolerance can be improved by discharging the minority carriers accumulated in the base region to the outside. Therefore, for example, a contact made of a p-type semiconductor region or a metal material is formed so as to penetrate a source region from a source electrode and reach a base layer. However, since such a contact is provided so as to penetrate the source region, an area of the source region decreases, and on-resistance of a semiconductor device increases.

### BRIEF DESCRIPTION OF THE DRAWINGS

FIG. 1 is a plan view of a semiconductor device according to a first embodiment;

FIG. 2 is a cross-sectional view of the semiconductor device according to the first embodiment, taken along line I-I in FIG. 1;

FIG. 3 is another cross-sectional view of the semiconductor device according to the first embodiment, and is a view illustrating a part of a cross section taken along line II-II in FIG. 1;

FIG. 4A is a cross-sectional view illustrating an example of a manufacturing process of the semiconductor device according to the first embodiment;

FIG. 4B is a cross-sectional view illustrating an example of the manufacturing process of the semiconductor device according to the first embodiment, following FIG. 4A;

FIG. 4C is a cross-sectional view illustrating an example of the manufacturing process of the semiconductor device according to the first embodiment, following FIG. 4B;

FIG. 4D is a cross-sectional view illustrating an example of the manufacturing process of the semiconductor device according to the first embodiment, following FIG. 4C;

FIG. 5 is a cross-sectional view of a semiconductor device according to a second embodiment, taken along line I-I in FIG. 1;

FIG. 6 is another cross-sectional view of the semiconductor device according to the second embodiment, and is a view illustrating a part of a cross section taken along line II-II in FIG. 1;

FIG. 7A is a cross-sectional view illustrating an example of a manufacturing process of the semiconductor device according to the second embodiment;

FIG. 7B is a cross-sectional view illustrating an example of the manufacturing process of the semiconductor device according to the second embodiment, following FIG. 7A;

FIG. 7C is a cross-sectional view illustrating an example of the manufacturing process of the semiconductor device according to the second embodiment, following FIG. 7B;

FIG. 7D is a cross-sectional view illustrating an example of the manufacturing process of the semiconductor device according to the second embodiment, following FIG. 7C;

FIG. 7E is a cross-sectional view illustrating an example of the manufacturing process of the semiconductor device according to the second embodiment, following FIG. 7D;

FIG. 8 is a plan view of a semiconductor device according to a third embodiment; and

FIG. 9 is a cross-sectional view of the semiconductor device according to the third embodiment, taken along line III-III in FIG. 8.

### DETAILED DESCRIPTION

A semiconductor device according to an embodiment includes: a semiconductor layer including a first main surface and a second main surface; a first electrode provided on the first main surface; a second electrode provided on the second main surface; a first semiconductor region of a first conductivity type, the first semiconductor region being provided in the semiconductor layer and located on the second electrode; a plurality of insulating regions provided in the semiconductor layer, configured to reach the first semiconductor region from the first main surface, and formed to extend in a second direction orthogonal to a first direction from the second electrode toward the first electrode; a plurality of third electrodes provided in the plurality of insulating regions and formed to extend in the second direction; a second semiconductor region of a second conductivity type provided, in the semiconductor layer, to be sandwiched between the plurality of insulating regions, to be located on the first semiconductor region, and to extend in the second direction; a third semiconductor region of the first conductivity type, the third semiconductor region being provided in the semiconductor layer and located between the second semiconductor region and the first electrode; and a carrier conduction part provided to extend in the second direction in the second semiconductor region and electrically connected to the first electrode via a connection part not penetrating the third semiconductor region.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, the same elements as those described in the previous drawings are denoted by the same reference numerals, and a detailed description thereof is appropriately omitted.

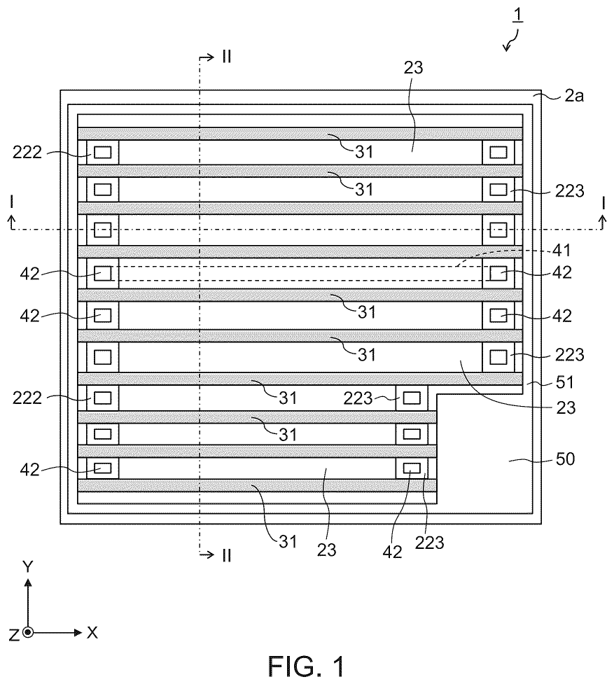

For convenience of description, an XYZ orthogonal coordinate system is adopted as illustrated in FIGS. 1 to 3. The Z-axis direction is a stacking direction (thickness direction) of a semiconductor device. In the Z-axis direction, the source electrode side is also referred to as “upper”, and the drain electrode side is also referred to as “lower”. However, this expression is used for convenience and is independent of the direction of gravity. The X-axis direction is a second direction in the claims. The Z- axis direction is a first direction in the claims.

In the following description, notations of n⁺, n, n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are contained in each region, these notations represent the relative level of net impurity concentration after these impurities have been compensated. An n-type, an n⁺-type, and an n-type are examples of a first conductivity type in the claims. A p-type, a p⁺-type, and a p⁻-type are examples of a second conductivity type in the claims. It is noted that, in the following description, the n-type and the p-type may be reversed. That is, the first conductivity type may be the p-type.

### First Embodiment

### Semiconductor Device

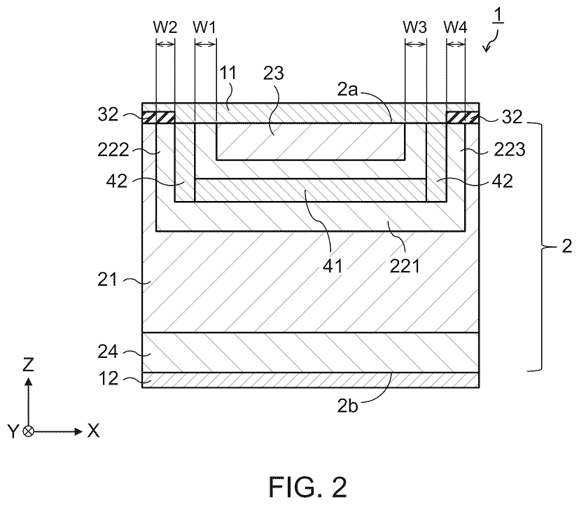

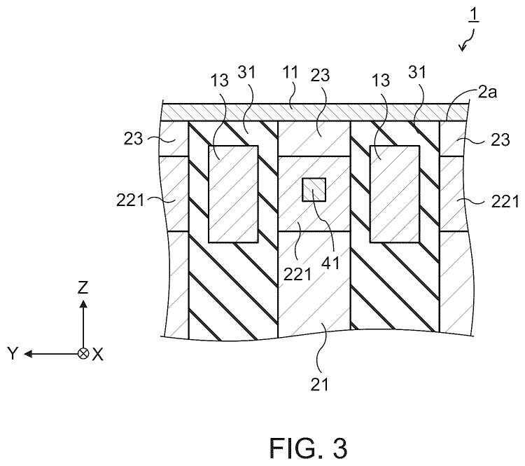

A semiconductor device 1 according to a first embodiment will be described with reference to FIGS. 1 to 3. FIG. 1 is a plan view of a semiconductor device according to the first embodiment. FIG. 2 is a cross-sectional view of the semiconductor device according to the first embodiment, taken along line I-I in FIG. 1. FIG. 3 is another cross-sectional view of the semiconductor device according to the first embodiment, and is a view illustrating a part of a cross section taken along line II-II in FIG. 1. It is noted that, in FIG. 1, a source electrode 11 and an interlayer insulating film 32 are omitted. In addition, one of the plurality of carrier conduction parts 41 is illustrated in FIG. 1 for easy understanding of the drawing.

The semiconductor device 1 according to the present embodiment is a vertical MOSFET or the like. Hereinafter, a case in which the semiconductor device 1 is the vertical MOSFET will be described.

As illustrated in FIG. 2, the semiconductor device 1 includes a semiconductor layer 2, the source electrode 11 provided on an upper surface (first main surface) 2a of the semiconductor layer 2, and a drain electrode 12 provided on a lower surface (second main surface) 2b of the semiconductor layer 2. It is noted that, for convenience of description, the upper surface 2a and the lower surface 2b of the semiconductor layer 2 are substantially planar, but this does not limit the shape of the semiconductor layer 2.

The semiconductor layer 2 is disposed on the drain electrode 12. The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. It is noted that the semiconductor layer 2 may be made of a compound semiconductor such as silicon carbide (SiC) or gallium nitride (GaN).

The source electrode 11 is an electrode that functions as a source electrode of the MOSFET. The source electrode 11 is made of, for example, copper (Cu), titanium (Ti), tungsten (W), aluminum (Al), or the like. The source electrode 11 is an example of a first electrode in the claims.

The drain electrode 12 is an electrode that functions as a drain electrode of the MOSFET. The drain electrode 12 is made of, for example, metal such as copper, titanium, tungsten, or aluminum. The drain electrode 12 is an example of a second electrode in the claims.

In the semiconductor layer 2, a drift region 21, a drain region 24, a gate insulating film 31, a gate electrode 13, a base region 221, a connection region 222, a connection region 223, and a source region 23 are provided. It is noted that an interlayer insulating film 32 is provided on a part of the upper surface 2a of the semiconductor layer 2. Hereinafter, each component provided in the semiconductor layer 2 will be described.

The drift region 21 is a semiconductor region that functions as a drift region of the MOSFET. The drift region 21 is disposed on the drain region 24 (above the drain electrode 12). The drift region 21 is, for example, an n-type semiconductor region. The n-type impurity concentration of the drift region 21 is, for example, 1×10¹⁵ cm⁻³ or more and 2×10¹⁶ cm⁻³ or less. The drift region 21 is an example of a first semiconductor region in the claims.

The drain region 24 is disposed between the drift region 21 and the drain electrode 12. The drain region 24 is a semiconductor region that functions as a drain region of the MOSFET. The drain region 24 is, for example, an n⁺-type semiconductor region. The n-type impurity concentration of the drain region 24 is, for example, 1×10¹⁸ cm⁻³ or more and 1×10²¹ cm⁻³ or less. The drain region 24 is an example of a first semiconductor region in the claims.

It is noted that the first semiconductor region in the claims may include both the drift region 21 and the drain region 24, or may include either one of the drift region 21 and the drain region 24.

As illustrated in FIG. 3, a plurality of gate insulating films 31 are provided so as to reach the drift region 21 from the upper surface 2a of the semiconductor layer 2. As illustrated in FIG. 1, each gate insulating film 31 extends in the X direction. The gate insulating film 31 is made of a dielectric that covers sidewalls of a plurality of gate trenches provided on the upper surface 2a of the semiconductor layer 2 so as to extend in the X direction. The gate insulating film 31 is made of, for example, a dielectric such as silicon oxide or silicon nitride. The gate insulating film 31 is an example of an insulating region in the claims. It is noted that, in the present embodiment, a gate trench is provided on the upper surface 2a of the semiconductor layer 2, but this does not limit the shape of the semiconductor layer 2.

As illustrated in FIG. 3, the gate electrode 13 is provided in each gate insulating film 31. The gate electrode 13 is an electrode that functions as a gate electrode of the MOSFET. Each gate electrode 13 extends in the X direction. The gate electrode 13 is electrically insulated from the semiconductor layer 2 by the gate insulating film 31. In the example illustrated in FIG. 3, the upper end of the gate electrode 13 is at a position higher than the upper end of the base region 221 to be described later, and the lower end of the gate electrode 13 is at a position lower than the lower end of the base region 221. The gate electrode 13 is disposed adjacent to (facing) the base region 221 with the gate insulating film 31 interposed therebetween. The gate electrode 13 is made of, for example, polysilicon containing the p-type impurity or the n-type impurity. The gate electrode 13 is an example of a third electrode in the claims.

It is noted that, although not illustrated in the drawing, a field plate (FP) electrode may be provided below the gate electrode 13 in each gate insulating film 31. Each FP electrode is electrically connected to the source electrode 11. By providing such an FP electrode, when the MOSFET is in the off state, a depletion layer extends in the drift region 21 around the FP electrode by a voltage applied to a space between the source electrode 11 and the drain electrode 12. This depletion layer is connected to a depletion layer extending around the adjacent FP electrode, thereby making it possible to improve a withstand voltage of the semiconductor device 1.

As illustrated in FIG. 3, the respective base regions 221 are provided so as to be sandwiched between the gate insulating films 31. As illustrated in FIG. 2, the base region 221 is located on the drift region 21 and extends in the X-axis direction. The base region 221 is a semiconductor region that functions as a base region of the MOSFET. When a voltage is applied to the gate electrode 13, a channel is formed in the base region 221, and carriers flow between the drift region 21 and the source region 23. The base region 221 is, for example, the p-type semiconductor region. The p-type impurity concentration of the base region 221 is, for example, 1×10¹⁶ cm⁻³ or more and 1×10²⁰ cm⁻³ or less. The base region 221 is an example of a second semiconductor region in the claims.

As illustrated in FIG. 2, the connection region 222 and the connection region 223 are provided between opposite end parts of the base region 221 in the X-axis direction and the source electrode 11. More specifically, the connection region 222 extends in the Z-axis direction from one end part (left end in FIG. 2) of the base region 221 in the X-axis direction to the source electrode 11, and connects the base region 221 to the source electrode 11. The connection region 223 extends in the Z-axis direction from the other end part (the right end in FIG. 2) of the base region 221 in the X-axis direction to the source electrode 11, and connects the base region 221 to the source electrode 11. The connection region 222 is an example of a first connection region in the claims. The connection region 223 is an example of a second connection region in the claims.

The connection region 222 and the connection region 223 separate the drift region 21 and the source region 23 to be described later, and separate the drift region 21 and a connection part 42 to be described later. In the present embodiment, the connection region 222 and the connection region 223 are p-type semiconductor regions having p-type impurity concentrations equal to that of the base region 221. As a result, the base region 221, the connection region 222, and the connection region 223 can be collectively formed. It is noted that both or any one of the connection region 222 and the connection region 223 may be a p-type semiconductor region having a p-type impurity concentration different from that of the base region 221, or may be an insulating region made of an insulating material such as silicon oxide or silicon nitride.

Further, in the present embodiment, the widths of the connection region 222 and the connection region 223 in the X-axis direction are equal to each other, but the widths of the connection region 222 and the connection region 223 in the X-axis direction may be different from each other.

The carrier conduction part 41 is provided in each base region 221. As illustrated in FIGS. 1 and 2, the carrier conduction part 41 extends in the X-axis direction. As illustrated in FIG. 3, the carrier conduction part 41 is provided at a position equidistant from the adjacent gate electrodes 13 in the Y-axis direction, and is located at the center of the base region 221 in the Z-axis direction. It is noted that the position of the carrier conduction part 41 in the Y-axis direction may be biased to one of the adjacent gate electrodes 13 as long as the carrier conduction part 41 is within a range not contacting the gate insulating film 31. In addition, the position of the carrier conduction part 41 in the Z-axis direction may not be located at the center of the base region 221 as long as the carrier conduction part 41 is within a range not contacting the drift region 21. For example, the upper end of the carrier conduction part 41 may be approximately the same height as the upper end of the base region 221.

Carriers accumulated in the base region 221 conduct the inside of the carrier conduction part 41. In the present embodiment, the carrier conduction part 41 is a p⁺-type semiconductor region having a p-type impurity concentration higher than that of the base region 221. The p-type impurity concentration of the carrier conduction part 41 is, for example, 5×10¹⁸ cm⁻³ or more and 1×10²² cm⁻³ or less. As described above, since the carrier conduction part 41 has a p-type impurity concentration higher than that of the base region 221, carriers move more easily in the carrier conduction part 41 than in the base region 221.

In addition, the carrier conduction part 41 is electrically connected to the source electrode 11 via a connection part not penetrating the source region 23 (not sandwiched by the source region 23). Minority carriers injected from the base region 221 into the carrier conduction part 41 are conducted toward the source electrode 11 through the connection part. As illustrated in FIG. 2, in the present embodiment, the connection part 42 is provided in each of the connection region 222 and the connection region 223, and electrically connects the carrier conduction part 41 to the source electrode 11. More specifically, the connection part 42 in the connection region 222 electrically connects one end part (left end in FIG. 2) of the carrier conduction part 41 to the source electrode 11. The connection part 42 in the connection region 223 electrically connects the other end part (right end in FIG. 2) of the carrier conduction part 41 to the source electrode 11. None of the connection parts 42 penetrates the source region 23. As a result, carriers that move in the carrier conduction part 41 and reach the opposite ends of the carrier conduction part 41 pass through the connection part 42 and are discharged to the source electrode 11. The connection part 42 contains metal or polysilicon doped with impurities. It is noted that the connection part 42 may include a semiconductor region of the second conductivity type. The connection part 42 in the connection region 222 is an example of a connection part in the claims. The connection part 42 in the connection region 223 is an example of a second connection part in the claims.

It is noted that either the connection region 222 or the connection region 223 may be omitted. In this case as well, the carrier conduction part 41 and the source electrode 11 are electrically connected to each other by the connection part 42 provided in the remaining other connection region.

As illustrated in FIG. 2, the connection part 42 in the connection region 222 is located at the center of the connection region 222 in the X-axis direction. That is, a width W1 of the connection region 222 between the connection part 42 and the source region 23 is substantially equal to a width W2 of the connection region 222 between the connection part 42 and the drift region 21. Further, the connection part 42 in the connection region 223 is located at the center of the connection region 223 in the X-axis direction. That is, a width W3 of the connection region 223 between the connection part 42 and the source region 23 is substantially equal to a width W4 of the connection region 223 between the connection part 42 and the drift region 21. It is noted that the width W1 may be larger than the width W2, the width W3 may be larger than the width W4, or on the contrary, the width W2 may be larger than the width W1, or the width W4 may be larger than the width W3 in order to secure a margin of positional deviation of the connection part 42 in the X-axis direction.

As illustrated in FIG. 2, the source region 23 is provided between the base region 221 and the source electrode 11. The source region 23 is a semiconductor region that functions as a source region of the MOSFET. The source region 23 is, for example, an n⁺-type semiconductor region. The n-type impurity concentration of the source region 23 is, for example, 1×10¹⁸ cm⁻³ or more and 1×10²² cm⁻³ or less. The source region 23 is an example of a third semiconductor region in the claims.

As illustrated in FIG. 1, a gate pad 50 and a gate wiring 51 connected to the gate pad 50 are provided on the upper surface 2a of the semiconductor layer 2. The plurality of gate electrodes 13 are electrically connected to the gate pad 50 via the gate wiring 51.

It is noted that the planar shape of the semiconductor device 1, that is, the arrangement of each component on the upper surface 2a of the semiconductor layer 2 is not limited to the example illustrated in FIG. 1, and is freely selected.

### Manufacturing Method of Semiconductor Device

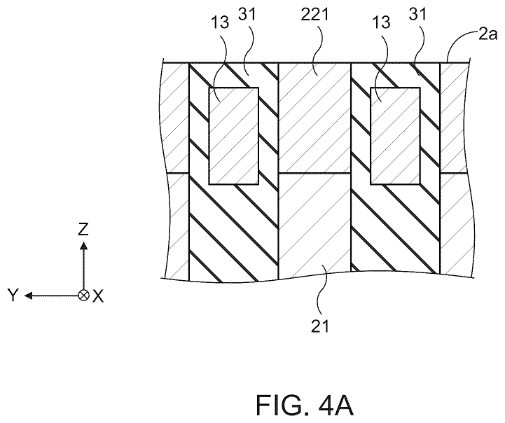

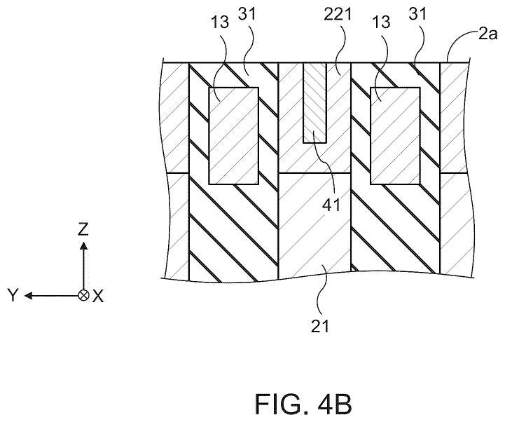

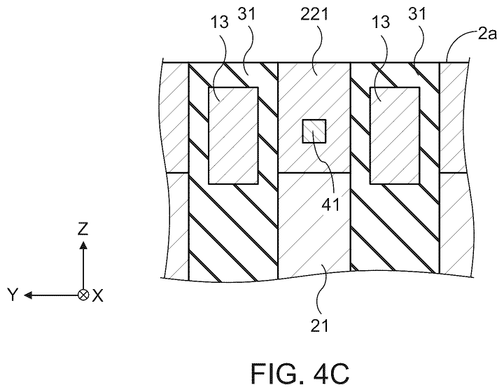

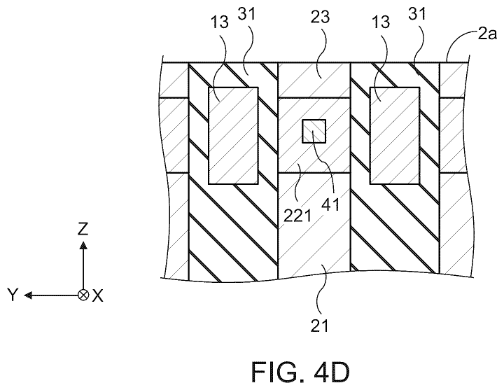

Next, an example of a manufacturing method of the semiconductor device 1 according to the present embodiment will be described with reference to FIGS. 4A to 4D. FIGS. 4A to 4D are process cross-sectional views illustrating the manufacturing method of the semiconductor device 1, and are views corresponding to a part of a cross section taken along line II-II in FIG. 1.

First, as illustrated in FIG. 4A, a semiconductor layer including the drift region 21, the gate insulating film 31 reaching the drift region 21 from the upper surface 2a, the plurality of gate electrodes 13 respectively provided in the gate insulating films 31, and the plurality of base regions 221 sandwiched between the gate insulating films 31 is prepared.

This semiconductor layer is obtained, for example, as follows. First, a semiconductor layer including the drift region 21 is prepared. Thereafter, a gate trench is formed from the upper surface 2a of the semiconductor layer by reactive ion etching (RIE) or the like. Thereafter, an insulating material is deposited in the gate trench by chemical vapor deposition (CVD) or the like, thereby forming the gate insulating film 31. Thereafter, a part of the gate insulating film 31 is removed by RIE or the like.

Thereafter, a conductive material such as polysilicon is deposited by CVD or the like, and the excess conductive material is etched back, thereby forming the gate electrode 13. Thereafter, an insulating material is deposited by CVD or the like, thereby burying the gate electrode 13.

Thereafter, the base region 221, the connection region 222, and the connection region 223 are formed by ion-implanting p-type impurities into the upper surface 2a of the semiconductor layer. Specifically, the base region 221 is formed by ion-implanting p-type impurities into a surface of the upper surface 2a of the semiconductor layer, in which the surface is sandwiched between the gate insulating films 31. On the upper surface 2a of the semiconductor layer, p-type impurities are ion-implanted to peripheries around opposite end parts of the gate insulating film 31 in the X-axis direction, thereby forming the connection region 222 and the connection region 223. The connection region 222 and the connection region 223 may be formed in the same ion implantation process as the base region 221.

Through the above-described processes, the semiconductor layer illustrated in FIG. 4A is formed.

Next, as illustrated in FIG. 4B, p-type impurities are ion-implanted into the base region 221, thereby forming the carrier conduction part 41.

Next, as shown in FIG. 4C, n-type impurities are ion-implanted into the carrier conduction part 41 from the upper surface 2a. As a result, the p-type impurities already implanted in the base region 221 are compensated by the implanted n-type impurities, while the p-type impurity concentration in the base region 221 remains constant. Therefore, the net p-type impurity concentration at the upper part of the carrier conduction part 41 is lowered. In the example illustrated in FIG. 4C, the net p-type impurity concentration at the upper part of the carrier conduction part 41 is lowered to the same level as the base region 221. It is noted that, in the ion implantation in this step, a resist or the like used at the time of forming the carrier conduction part 41 may be used as it is.

Next, as illustrated in FIG. 4D, n-type impurities are ion-implanted into the base region 221 from the upper surface 2a, thereby forming the source region 23.

Next, although not illustrated in the drawing, trenches reaching the carrier conduction part 41 from the upper surface 2a are formed in the connection region 222 and the connection region 223 by RIE or the like. Thereafter, a conductive material is deposited so as to fill the trench by CVD, physical vapor deposition (PVD), or the like, thereby forming the connection part 42. The conductive material is, for example, a metal material containing copper, titanium, tungsten, aluminum, or the like, polysilicon, or the like. In the case of polysilicon, p-type or n-type impurities may be contained.

Next, the interlayer insulating film 32 for insulating the source electrode 11 from the drift region 21 is formed on a part of the upper surface 2a of the semiconductor layer 2. Thereafter, the interlayer insulating film 32 is buried, and the source electrode 11 is formed so as to be in contact with the source region 23.

Next, the drain region 24 is formed by ion-implanting n-type impurities into the lower surface 2b of the semiconductor layer 2. Thereafter, the drain electrode 12 is formed so as to cover the lower surface 2b of the semiconductor layer 2.

Through the above-described processes, the semiconductor device 1 is manufactured.

As described above, the semiconductor device 1 according to the present embodiment includes the carrier conduction part 41 provided to extend in the X-axis direction in the base region 221 and electrically connected to the source electrode 11 via the connection part 42 that does not penetrate the source region 23. As a result, while maintaining the area of the source region 23 on the upper surface 2a of the semiconductor layer 2, minority carriers remaining in the base region 221 can be promptly discharged to the source electrode 11 by the carrier conduction part 41 and the connection part 42.

Therefore, according to the present embodiment, it is possible to improve avalanche tolerance while preventing an increase in on-resistance of the semiconductor device 1.

It is noted that, in a case where a contact that reaches the base region 221 from the upper surface 2a of the semiconductor layer 2 is provided instead of providing the carrier conduction part 41 in the base region 221, it is necessary to extend the contact in the X-axis direction in order to sufficiently discharge minority carriers remaining in the base region 221. However, when such a contact is formed, positional deviation in the Y-axis direction may occur, and the position of the contact may deviate from the center of the source region 23 in the Y-axis direction. In this case, since resistance increases as the area of a part of the source region 23 on the upper surface 2a of the semiconductor layer 2 decreases, there is a possibility that on-resistance of the semiconductor device increases. In addition, when the contact is made of the p-type semiconductor region, the base region 221 between the contact and the gate insulating film 31 is narrowed and, as such, it is difficult to form a channel. As a result, a threshold voltage of the MOSFET may be affected.

On the other hand, in the semiconductor device 1 according to the present embodiment, the carrier conduction part 41 is buried in the base region 221, thereby being formed independently of (without interference with) the source region 23. As a result, it is possible to prevent an influence on the source region 23 due to positional deviation of the carrier conduction part 41 in the Y-axis direction. For example, even when the position of the carrier conduction part 41 deviates in the Y-axis direction, it is possible not only to prevent generation of a conduction path having a large resistance in the source region 23, but also to prevent an increase in on-resistance of the semiconductor device 1.

### Second Embodiment

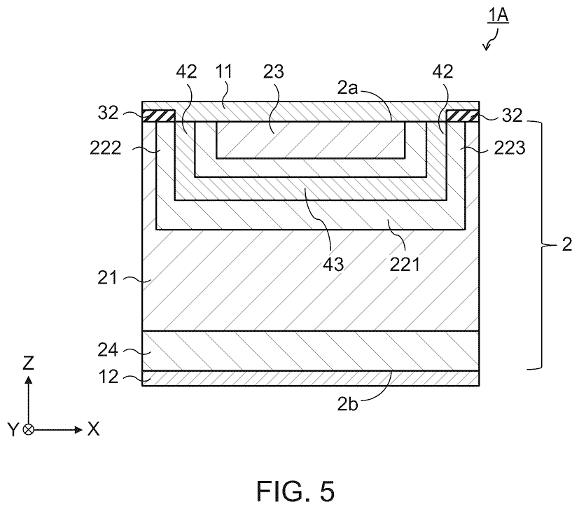

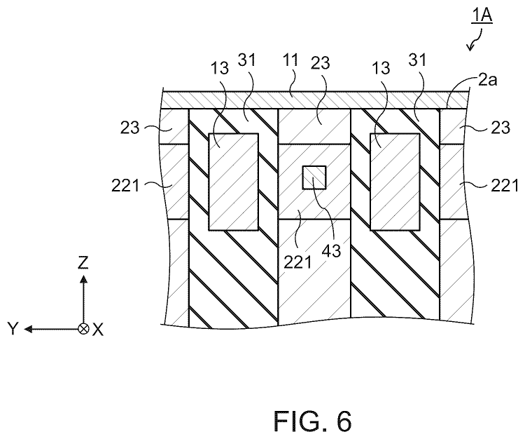

A semiconductor device 1A according to a second embodiment will be described with reference to FIGS. 5 and 6. FIG. 5 is a cross-sectional view of the semiconductor device 1A according to the second embodiment, and is a view illustrating a part of a cross section taken along line I-I in FIG. 1. FIG. 6 is another cross-sectional view of the semiconductor device 1A according to the second embodiment, and is a view illustrating a part of a cross section taken along line II-II in FIG. 1.

One of the differences between the second embodiment and the first embodiment is a constituent material of the carrier conduction part. Hereinafter, the semiconductor device 1A according to the present embodiment will be described focusing on differences from the first embodiment.

As illustrated in FIGS. 5 and 6, the semiconductor device 1A according to the present embodiment includes a carrier conduction part 43 instead of the carrier conduction part 41 of the first embodiment. The carrier conduction part 43 is a conductor containing metal or polysilicon doped with impurities. As a result, similarly to the first embodiment, carriers are more easily moved in the carrier conduction part 43 than in the base region 221.

It is noted that a position of the carrier conduction part 43 in the Z-axis direction may be a position different from that in FIG. 6 as long as the position is within a range not contacting the drift region 21. For example, the upper end of the carrier conduction part 43 may be approximately the same height as the upper end of the base region 221.

### Manufacturing Method of Second Embodiment

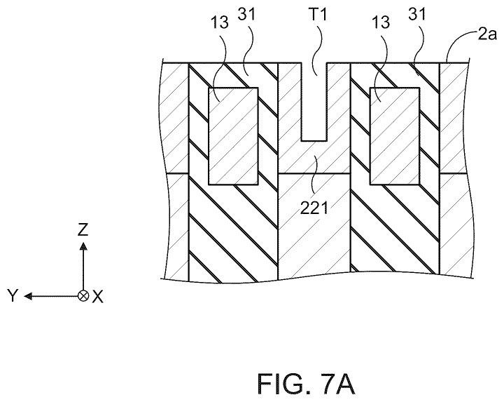

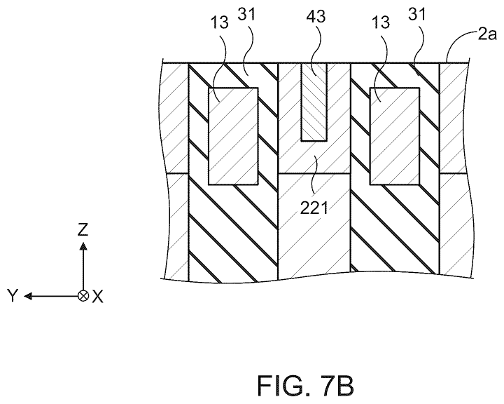

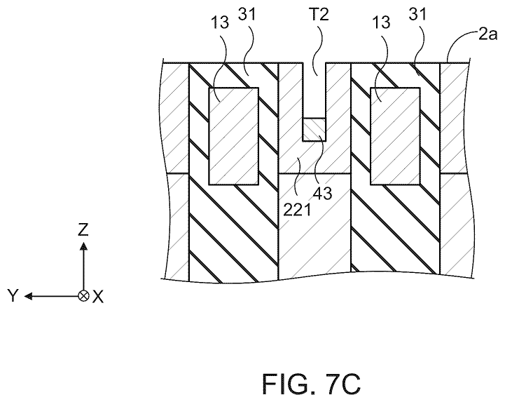

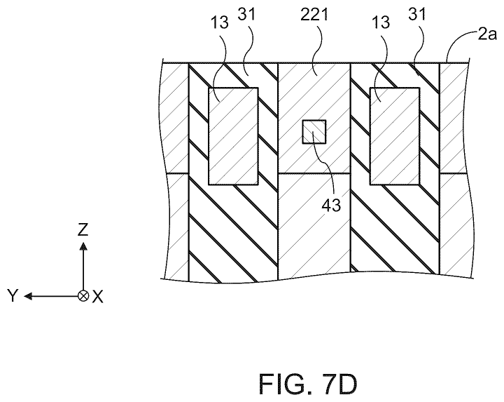

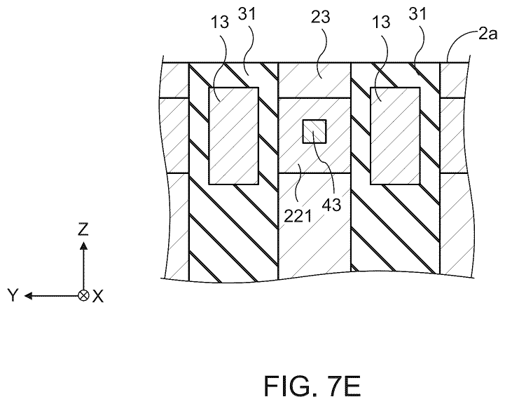

Next, an example of a manufacturing method of the semiconductor device 1A according to the present embodiment will be described with reference to FIGS. 4A and 7A to 7E. FIGS. 7A to 7E are process cross-sectional views illustrating the manufacturing method of the semiconductor device 1A, and are views corresponding to a part of a cross section taken along line II-II in FIG. 1.

First, as in the first embodiment, the semiconductor layer illustrated in FIG. 4A is prepared.

Next, as illustrated in FIG. 7A, the base region 221 is partially removed by RIE or the like, thereby forming a trench T1. In the present embodiment, a trench (not illustrated) is also formed in each of the connection region 222 and the connection region 223 at the same time as the formation of the trench T1.

Next, as illustrated in FIG. 7B, a conductive material is deposited so as to fill the trench T1 by CVD, PVD, or the like, thereby forming the carrier conduction part 43. In the present embodiment, the connection part 42 is formed by depositing a conductive material also in the trenches formed in the connection region 222 and the connection region 223 at the same time as the formation of the carrier conduction part 43. The conductive material is, for example, a metal material containing copper, titanium, tungsten, aluminum, or the like, polysilicon, or the like.

Next, as illustrated in FIG. 7C, a part of the deposited carrier conduction part 43 is removed by wet etching or the like, thereby forming a trench T2 on the carrier conduction part 43. It is noted that the connection part 42 is not removed in the connection region 222 and the connection region 223.

Next, as illustrated in FIG. 7D, a p-type epitaxial layer is grown to bury the carrier conduction part 43 in the base region 221. It is noted that the p-type epitaxial layer is also formed on the base region 221 in the upper surface 2a of the semiconductor layer, but this portion is removed by RIE, chemical mechanical polishing (CMP), or the like.

Next, as illustrated in FIG. 7E, n-type impurities are ion-implanted into the upper part of the base region 221, thereby forming the source region 23.

Next, as in the first embodiment, the interlayer insulating film 32, the drain region 24, and the drain electrode 12 are formed.

Through the above-described processes, the semiconductor device 1A is manufactured.

As described above, with the semiconductor device 1A according to the second embodiment, similarly to the first embodiment, it is possible to improve avalanche tolerance while preventing an increase in on-resistance of the semiconductor device 1A.

Further, as in the first embodiment, in the present embodiment, the carrier conduction part 43 is buried in the base region 221, thereby being formed independently of (without interference with) the source region 23. As a result, it is possible to prevent an influence on the source region 23 due to positional deviation of the carrier conduction part 43 in the Y-axis direction. For example, even when the position of the carrier conduction part 43 deviates in the Y-axis direction, it is possible not only to prevent generation of a conduction path having a large resistance in the source region 23, but also to prevent an increase in on-resistance of the semiconductor device 1A.

Further, in the present embodiment, since the carrier conduction part 43 is a conductor, even when the carrier conduction part 43 deviates in the Y-axis direction, it is difficult to prevent a channel from being formed in the base region 221. Therefore, the carrier conduction part 43 of the present embodiment is allowed to deviate in the Y-axis direction from the carrier conduction part 41 of the first embodiment. Accordingly, for example, the semiconductor device 1A can be more easily manufactured. In addition, the influence on the threshold voltage can also be prevented.

In the present embodiment, since the carrier conduction part 43 and the connection part 42 can be formed at the same time, a manufacturing process can be simplified.

It is noted that the regrowth of the epitaxial layer described in FIG. 7D can also be applied to the manufacturing method of the first embodiment. In this case, after the carrier conduction part 41 is formed in FIG. 4B, the upper part of the carrier conduction part 41 is removed by RIE or the like, thereby forming a trench. Thereafter, the epitaxial layer is regrown to form a p-type semiconductor region similar to the base region 221 in the trench. The same configuration as that of FIG. 4C can be obtained by such a process.

### Third Embodiment

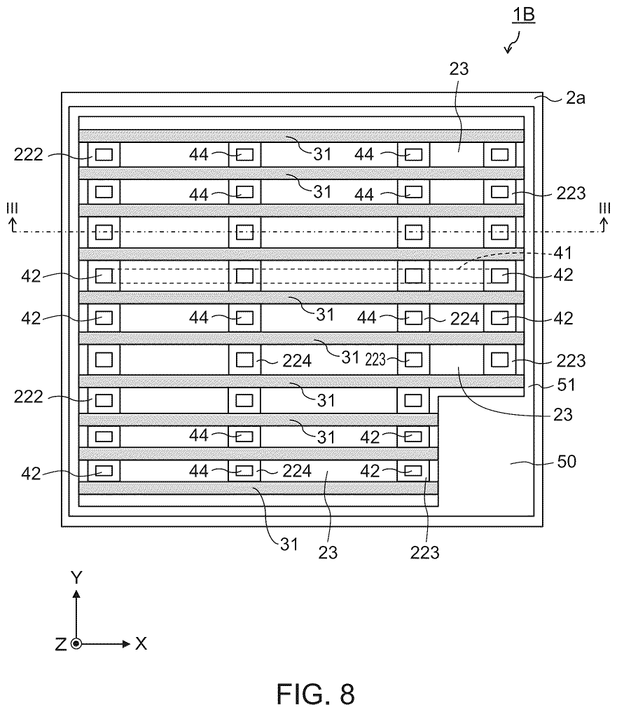

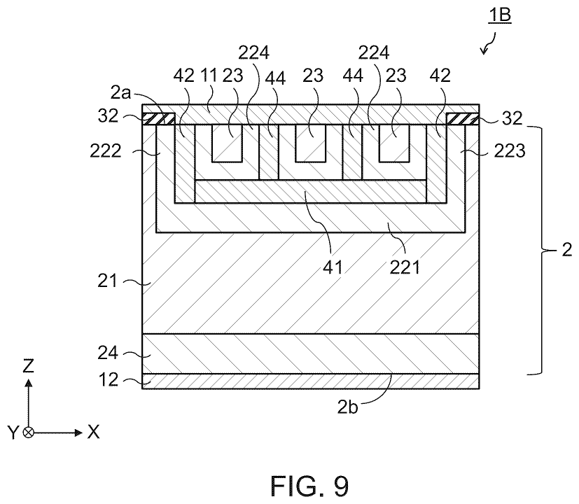

A semiconductor device 1B according to a third embodiment will be described with reference to FIGS. 8 and 9. FIG. 8 is a plan view of the semiconductor device 1B according to the third embodiment. FIG. 9 is a cross-sectional view of the semiconductor device 1B according to the third embodiment, taken along line III-III of FIG. 8.

One of the differences between the third embodiment and the first embodiment is the number of connection parts. Hereinafter, the semiconductor device 1B according to the present embodiment will be described focusing on differences from the first embodiment.

As illustrated in FIGS. 8 and 9, the semiconductor device 1B according to the present embodiment further includes two connection regions 224 located between the connection region 222 and the connection region 223 in the X-axis direction and sandwiched between the source regions 23. The connection region 224 extends from the base region 221 to the source electrode 11 in the Z-axis direction, and connects the base region 221 to the source electrode 11. The connection region 224 is an example of a third connection region in the claims. It is noted that the number of the connection regions 224 located between the connection region 222 and the connection region 223 in the X-axis direction is not limited to two, and may be any number.

In the present embodiment, the connection region 224 is a p-type semiconductor region having the same p-type impurity concentration as the base region 221, the connection region 222, and the connection region 223. As a result, the base region 221, the connection region 222, the connection region 223, and the connection region 224 can be collectively formed. It is noted that the connection region 224 may be a p-type semiconductor region having a p-type impurity concentration different from those of the base region 221, the connection region 222, and the connection region 223, or may be an insulating region made of an insulating material such as silicon oxide or silicon nitride.

In the connection region 224, a connection part 44 that electrically connects the carrier conduction part 41 to the source electrode 11 is provided. The connection part 44 includes metal or polysilicon doped with impurities. It is noted that the connection part 44 may include a semiconductor region of the second conductivity type. The connection part 44 is an example of a third connection part in the claims.

As described above, the semiconductor device 1B according to the present embodiment further includes at least one connection region 224 located between the connection region 222 and the connection region 223 and sandwiched between the source regions 23, and the connection part 44 is provided in the connection region 224. As a result, carriers remaining in the base region 221 are discharged more quickly. As a result, although on-resistance of the semiconductor device 1B is increased by the connection region 224 as compared with the semiconductor devices 1 and 1A described above, the avalanche tolerance of the semiconductor device 1B can be further improved.

It is noted that, in the semiconductor device 1B according to the present embodiment, the carrier conduction part 43 of the conductor may be provided instead of the carrier conduction part 41 which is a semiconductor region, similarly to the second embodiment.

In addition, the configuration of electrically connecting the carrier conduction parts 41 and 43 to the source electrode 11 in each of the above-described embodiments is not limited to the examples illustrated in FIGS. 2, 5, and 9, and is freely selected. For example, the connection region 222 and the connection region 223 may be provided further inside instead of being respectively provided at the opposite end parts of the base region 221. As another example, one or a plurality of connection regions extending from any portion of the base region 221 in the X-axis direction to the source electrode 11 may be provided, and the carrier conduction part 41 and the source electrode 11 may be electrically connected to each other via one or a plurality of connection parts provided in the connection regions, respectively. As still another example, a connection region extending from the base region 221 to the side surface of the semiconductor layer 2 may be provided, and the carrier conduction parts 41 and 43 and the source electrode 11 may be electrically connected to each other via a connection part provided in the connection region and a separate wiring or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a first main surface and a second main surface;
a first electrode provided on the first main surface;
a second electrode provided on the second main surface;
a first semiconductor region of a first conductivity type, the first semiconductor region being provided in the semiconductor layer and located on the second electrode;
a plurality of insulating regions provided in the semiconductor layer, configured to reach the first semiconductor region from the first main surface, and formed to extend in a second direction orthogonal to a first direction from the second electrode toward the first electrode;
a plurality of third electrodes provided in the plurality of insulating regions and formed to extend in the second direction;
a second semiconductor region of a second conductivity type provided, in the semiconductor layer, to be sandwiched between the plurality of insulating regions, to be located on the first semiconductor region, and to extend in the second direction;
a third semiconductor region of the first conductivity type, the third semiconductor region being provided in the semiconductor layer and located between the second semiconductor region and the first electrode; and
a carrier conduction part provided to extend in the second direction in the second semiconductor region and electrically connected to the first electrode via a connection part not penetrating the third semiconductor region.

2. The semiconductor device according to claim 1, wherein the carrier conduction part includes a semiconductor of the second conductivity type having an impurity concentration of the second conductivity type higher than an impurity concentration of the second conductivity type of the second semiconductor region.

3. The semiconductor device according to claim 2, wherein:
the connection part is connected to one end part of the carrier conduction part and is provided in a first connection region which is a semiconductor region of the second conductivity type; and
the first connection region is provided in the semiconductor layer and extends in the first direction from one end part of the second semiconductor region in the second direction to the first electrode.

4. The semiconductor device according to claim 3, further comprising a second connection part configured to electrically connect the other end part of the carrier conduction part to the first electrode without penetrating the third semiconductor region and provided in a second connection region which is the semiconductor region of the second conductivity type,
wherein the second connection region is provided in the semiconductor layer and extends in the first direction from the other end part of the second semiconductor region in the second direction to the first electrode.

5. The semiconductor device according to claim 4, wherein the first connection region and the second connection region include the semiconductor of the second conductivity type having the impurity concentration of the second conductivity type equal to the impurity concentration of the second conductivity type of the second semiconductor region.

6. The semiconductor device according to claim 4, further comprising:
a third connection region provided in the semiconductor layer, located between the first connection region and the second connection region, sandwiched between the third semiconductor regions, and connecting the second semiconductor region to the first electrode; and
a third connection part provided in the third connection region and configured to electrically connect the carrier conduction part to the first electrode.

7. The semiconductor device according to claim 1, wherein the carrier conduction part contains metal or polysilicon.

8. The semiconductor device according to claim 7, wherein
the connection part is connected to one end part of the carrier conduction part and is provided in a first connection region which is a semiconductor region of the second conductivity type, and
the first connection region is provided in the semiconductor layer and extends in the first direction from one end part of the second semiconductor region in the second direction to the first electrode.

9. The semiconductor device according to claim 8, further comprising a second connection part configured to electrically connect the other end part of the carrier conduction part to the first electrode without penetrating the third semiconductor region and provided in a second connection region which is the semiconductor region of the second conductivity type,
wherein the second connection region is provided in the semiconductor layer and extends in the first direction from the other end part of the second semiconductor region in the second direction to the first electrode.

10. The semiconductor device according to claim 9, wherein the first connection region and the second connection region include a semiconductor of the second conductivity type having an impurity concentration of the second conductivity type equal to an impurity concentration of the second conductivity type of the second semiconductor region.

11. The semiconductor device according to claim 9, further comprising:
a third connection region provided in the semiconductor layer, located between the first connection region and the second connection region, sandwiched between the third semiconductor regions, and connecting the second semiconductor region to the first electrode; and
a third connection part provided in the third connection region and configured to electrically connect the carrier conduction part to the first electrode.

12. The semiconductor device according to claim 1, wherein the carrier conduction part is provided at a position equidistant from the adjacent third electrodes.

13. The semiconductor device according to claim 12, wherein the connection part is connected to one end part of the carrier conduction part and is provided in a first connection region which is a semiconductor region of the second conductivity type, and
the first connection region is provided in the semiconductor layer and extends in the first direction from one end part of the second semiconductor region in the second direction to the first electrode.

14. The semiconductor device according to claim 13, further comprising a second connection part configured to electrically connect the other end part of the carrier conduction part to the first electrode without penetrating the third semiconductor region and provided in a second connection region which is the semiconductor region of the second conductivity type,
wherein the second connection region is provided in the semiconductor layer and extends in the first direction from the other end part of the second semiconductor region in the second direction to the first electrode.

15. The semiconductor device according to claim 14, wherein the first connection region and the second connection region include a semiconductor of the second conductivity type having an impurity concentration of the second conductivity type equal to an impurity concentration of the second conductivity type of the second semiconductor region.

16. The semiconductor device according to claim 1, wherein
the connection part is connected to one end part of the carrier conduction part and is provided in a first connection region which is a semiconductor region of the second conductivity type, and
the first connection region is provided in the semiconductor layer and extends in the first direction from one end part of the second semiconductor region in the second direction to the first electrode.

17. The semiconductor device according to claim 16, further comprising a second connection part configured to electrically connect the other end part of the carrier conduction part to the first electrode without penetrating the third semiconductor region and provided in a second connection region which is the semiconductor region of the second conductivity type,
wherein the second connection region is provided in the semiconductor layer and extends in the first direction from the other end part of the second semiconductor region in the second direction to the first electrode.

18. The semiconductor device according to claim 17, wherein the first connection region and the second connection region include a semiconductor of the second conductivity type having an impurity concentration of the second conductivity type equal to an impurity concentration of the second conductivity type of the second semiconductor region.

19. The semiconductor device according to claim 17, further comprising:
a third connection region provided in the semiconductor layer, located between the first connection region and the second connection region, sandwiched between the third semiconductor regions, connecting the second semiconductor region to the first electrode; and
a third connection part provided in the third connection region and configured to electrically connect the carrier conduction part to the first electrode.

20. The semiconductor device according to claim 1, wherein the connection part includes metal or polysilicon.
